(19) United States
(12) Patent Application Publication
(10) Pub. No.: US 2014/0034909 A1
(43) Pub. Date: Feb. 6, 2014

(54) THIN-FILM BALLISTIC SEMICONDUCTOR WITH ASYMMETRIC CONDUCTANCE

(71) Applicants: Joseph V. Mantese, Ellington, CT (US); Eric S. Landry, West Hartford, CT (US); Slade R. Culp, Coventry, CT (US)

(72) Inventors: Joseph V. Mantese, Ellington, CT (US); Eric S. Landry, West Hartford, CT (US); Slade R. Culp, Coventry, CT (US)

(73) Assignee: HAMILTON SUNDSTRAND CORPORATION, Windsor Locks, CT (US)

(21) Appl. No.: 13/565,065

(22) Filed: Aug. 2, 2012

(51) Int. Cl. H01L 29/66

(52) U.S. Cl. 257/29; 257/E29.166

(57) ABSTRACT

A thermoelectric structure comprises a thin thermoelectric film extending in a plane between parallel first and second shorting bars. A plurality of curved ballistic scattering guides are formed in a magnetic field region of the thin thermoelectric film subjected to a local, substantially uniform, nonzero magnetic field normal to the plane of the thin thermoelectric film.

### BACKGROUND

The present invention relates generally to thermoelectric materials, and more particularly to a solid state thermoelectric structure with asymmetric ballistic conductance.

The ability to control the direction and magnitude of energy flow in one dimension (wire), two dimension (thin film), and three dimension (bulk) solid state components has been considered critical to device performance since the beginning of the electronic age. Directionality of thermal and electrical currents is a critical concern in thermoelectric devices, diodes, and other electronic valves. The dimensionless thermoelectric figure of merit, a measure of thermoelectric performance, is defined as

$$ZT = \frac{{S}^{2} σ T}{κ} , \qquad [ Equation 1 ]$$

where S, σ, κ and T are the Seebeck coefficient, electrical conductivity, thermal conductivity and absolute temperature respectively. The best bulk thermoelectric materials have ZT˜1.0 near room temperature, although there have recently been reports of p-type materials having ZT˜1.8. Materials with ZT˜1.5 have been demonstrated at higher temperatures. It is generally recognized that materials must exhibit at least ZT˜2 for thermoelectric devices to be viable for solid-state cooling, and that ZT˜5 is necessary to significantly impact commercial and military markets.

Thin film semiconductor and semi-metals show promise for substantial gains in ZT. Power factor (S²σ) in thin films can be increased due to charge confinement in an effectively two-dimensional film, and the resulting quantum mechanical peak in the electron density of states. If σ is increased while κ is decreased, ZT may be further improved. Unfortunately, increases in electrical conductivity σ (which typically arise due to increased dopant concentration) tend to lead to a corresponding increase in thermal conductivity κ, as thermal energy in a semiconductor is carried by both electrons and phonons (i.e., quantized lattice vibrations). According to the Wiedemann-Franz law, the ratio between σ and the electronic contribution to the thermal conductivity, κₑₗ, is

$$\frac{σ}{{κ}_{el}} = \frac{1}{LT} , \qquad [ Equation 2 ]$$

where L is the Lorentz number. Because the Lorentz number is constant for most materials, the ratio σ/κₑₗ is generally assumed to be fixed. Fortunately, the electrical conductivity and thermal conductivity appearing in Equation 1 correspond to opposite directions of carrier transport in the thermoelectric material. The relevant direction for the electrical conductivity is the direction in which the applied electric field drives charge (i.e. the forward current direction). The relevant direction for the thermal conductivity is the direction in which the temperature gradient drives charge (i.e. the reverse current direction). Thus, in the limit of zero phonon contribution to thermal transport,

$$ZT = \frac{{S}^{2}}{L} \frac{{σ}_{forward}}{{σ}_{reverse}} . \qquad [ Equation 3 ]$$

Improvements in ZT can be realized if the ratio between forward and reverse electrical conductivities σ_{forward}/σᵣₑᵥₑᵣₛₑ is maximized. One method for producing materials with σ_{forward}/σᵣₑᵥₑᵣₛₑ<1 by creating a series of asymmetric inclusions to alter current flow was presented in U.S. Patent application US2010/0044644 A1 entitled, “Composite Material with Anisotropic Electrical and Thermal Conductivities,” filed Aug. 19, 2008.

### SUMMARY

A thermoelectric structure comprises a thin thermoelectric film extending in a plane between parallel first and second shorting bars. A plurality of curved ballistic scattering guides are formed in a magnetic field region of the thin thermoelectric film subjected to a local, substantially uniform, nonzero magnetic field normal to the plane of the thin thermoelectric film.

### BRIEF DESCRIPTION OF THE DRAWINGS

FIG. 1 is a schematic view of a thermoelectric structure according to the present invention.

FIG. 2A is an illustrative trajectory plot of forward charge transport through the thermoelectric structure of FIG. 1.

FIG. 2B is an illustrative trajectory plot of reverse charge transport through the thermoelectric structure of FIG. 1.

### DETAILED DESCRIPTION

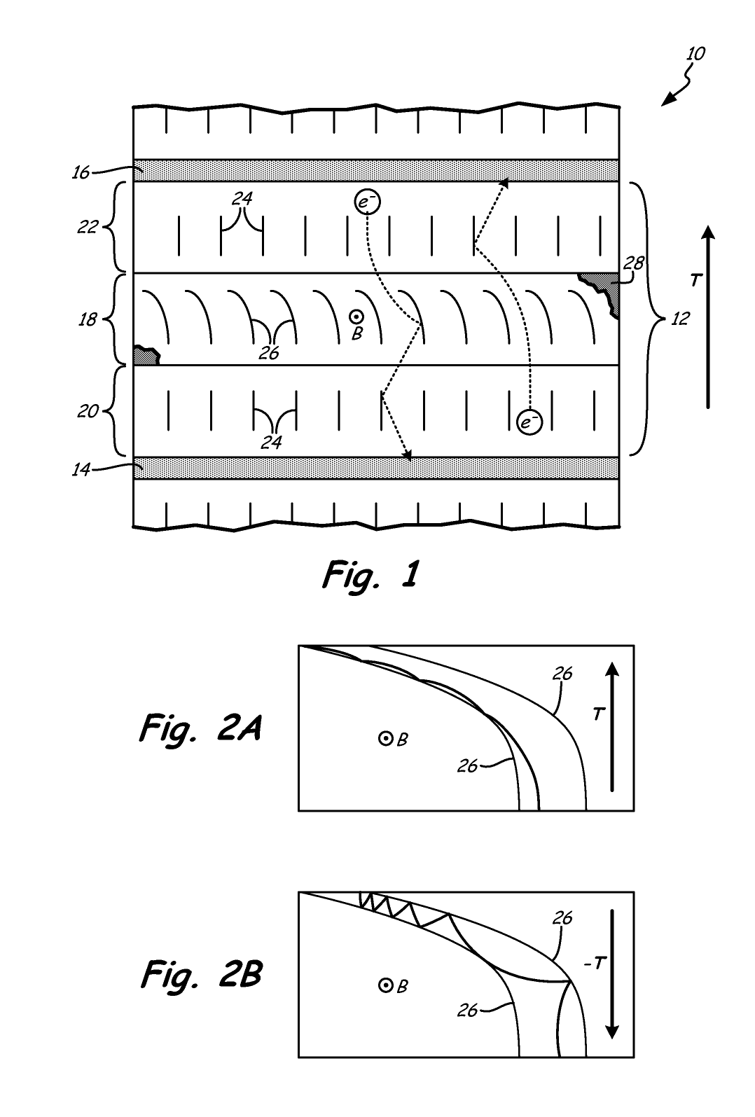

FIG. 1 is a schematic diagram of thermoelectric structure 10. FIG. 1 depicts asymmetric conductance region 12, shorting bars 14 and 16, magnetic field region 18, collimating regions 20 and 22, collimating guides 24, curved guides 26, and magnetic material 28.

Thermoelectric structure 10 is a substantially two-dimensional thermal diode formed on a thin semiconductor or semi-metal film. Thermoelectric structure 10 may be formed atom layer by atom layer by physical vapor deposition (PVD) methods such as molecular beam epitaxy (MBE), ion beam deposition (IBD), electron beam deposition (EBD), and others known to those skilled in the art. Thermoelectric structure 10 may, for instance, be formed of a high-mobility semiconductor or semi-metal such as graphene, gallium nitride, or silicon carbide, and has a thickness less than the mean free path of an electron in the material. Thermoelectric structure 10 includes at least one asymmetric conductance region 12 defined between shorting bars 14 and 16. Shorting bars 14 and 16 are thin regions of conductive material such as doped graphene or deposited layers of a conductor such as platinum or gold formed in or on thermoelectric structure 10. Shorting bars 14 and 16 act as electrodes, and collect charges passing through asymmetric conductance region 12. Thermoelectric structure 10 may comprise a plurality of repeating asymmetric conductance regions 12 arranged sequentially end-to-end in series, each separated from the next by a shorting bar. Similarly, a plurality of thermoelectric structures 10 can be stacked atop one another with intermediate isolating layers to form a three dimensional composite structure.

Magnetic field region 18 is a band of asymmetric conductance region 12 subjected to a localized magnetic field B oriented normal to the plane of thermoelectric structure 10 and out of the page, as depicted in FIG. 1. This magnetic field may be provided by depositing and polarizing magnetic material 28, a thin layer of magnetic material located atop and/or beneath the plane of thermoelectric structure 10, adjacent magnetic field region 18. Alternatively, magnetic field B may be an external field from, e.g., a magnetized coil. Magnetic field B is herein assumed for simplicity to be substantially uniform within magnetic field region 18, although all implementations of magnetic field B will of course vary somewhat over magnetic field region 18. Collimating regions 20 and 22 are bands of asymmetric conductance region 12 situated between magnetic field region 18 and shorting bars 14 and 16, respectively. Collimating regions 20 and 22 are regions with negligible magnetic field that serve to collimate ballistic charge flow between shorting bars 14 and 16 (in either direction).

Collimating regions 20 and 22 feature collimating guides 24, while magnetic field region 18 features curved guides 26. Collimating guides 24 and curved guides 26 are physical discontinuities along lines in thermoelectric structure 10 that act as scattering barriers to form channels in collimating regions 20 and 22 and magnetic field region 18, respectively, by ballistically scattering incident charge carriers. Adjacent collimating guides 24 may, for instance, be separated by a distance of approximately 1 nm-approximately 1 μm along an axis parallel to shorting bars 14 and 16, depending on the material and operating temperature of thermoelectric structure 10. Adjacent curved guides are separated by a similar distance. Collimating guides 24 and curved guides 26 may be created in a variety of ways, including by laser or mechanical scribing, surface level doping, field doping, or lithographic patterning. Collimating guides 24 are straight, parallel lines that act to focus charge carrier trajectories in collimating regions 20 and 22 along transport direction T or the opposite direction, −T. Curved guides 26 focus charge carriers moving in transit direction T from shorting bar 14 to shorting bar 16, but act to continually frustrate charge transport in opposite direction −T, as described in further detail below. Collimating guides 24 and curved guides 26 extend throughout the entire thickness of thermoelectric structure 10.

It is well known from elementary physics that a charge carrier of charge q, when travelling with vector velocity v through a magnetic field characterized by vector B, will experience a Lorentz force:

F=qv×B. [Equation 4]

A charge travelling in a plane through a magnetic field normal to that plane thus experiences a Lorenz force qvB in the plane and at right angles with v. The direction of curvature of a charge trajectory due to Lorenz force is opposite for conductors travelling with velocities v and −v, and of opposite signs q and −q. As depicted in FIG. 1, an electron travelling in transport direction T will deflect to the left under magnetic field B, while an electron travelling in the opposite direction −T will deflect to the right under magnetic field B. Curved guides 26 take advantage of this broken symmetry by allowing substantially unobstructed electron flow in transit direction T while frustrating electron flow in the opposite direction −T. Curved guides 26 form parallel curved channels in magnetic field region 18 that coincide with the arcs of curvature of forward conduction (i.e. in transit direction T), and thus more closely match the natural deflection trajectories of negative charge carriers moving in transit direction T than in the opposite direction −T. Thus, electrons travelling in transport direction T scatter on curved guides 26 substantially less and at wider angles than electrons travelling in the opposite direction −T. This asymmetry results in longer ballistic trajectories in the −T direction than in transmit direction T, with corresponding forward electrical conductivity σ_{forward}>reverse electrical conductivity σᵣₑᵥₑᵣₛₑ. This behavior is illustrated and described in further detail with respect to FIGS. 2A and 2B.

FIGS. 2A and 2B depict ballistic trajectories of negative charge carriers such as electrons through magnetic field region 18. FIG. 2A shows the trajectory of a charge carrier moving in transport direction T, while FIG. 2B shows the trajectory of a charge carrier moving in opposite direction −T. In both cases the Lorentz force causes the charge carrier to deflect in a counter-clockwise direction, according to the right-hand rule. In FIG. 2A, the charge carrier is deflected substantially to the right along a path defined by curved guides 26, and scatters at large angles with respect to curved guide 26. This scattering adds relatively little to the total path length of the charge carrier trajectory in FIG. 2A, corresponding to a high value of forward electrical conductivity σ_{forward}. In FIG. 2B, by contrast, the charge carrier is deflected substantially to the right, and scatters several times at progressively smaller angles with respect to curved guides 26. This scattering dramatically lengthens the total path length of the charge carrier trajectory in FIG. 2B, corresponding to a low value of reverse electrical conductivity σᵣₑᵥₑᵣₛₑ<σ_{forward}.

Thermoelectric structure 10 enables high values of ZT. Magnetic field regions 18 with perpendicularly applied magnetic fields B and curved guides 26 coinciding with arcs of curvature of charge carriers traveling in transport direction T can yield ratios of forward to reverse conductance σ_{forward}/σᵣₑᵥₑᵣₛₑ˜10, potentially enabling the creation of ZT>5 thermoelectric materials which would fundamentally change the coefficient of performance of solid state materials, potentially opening up their use for all solid state commercial refrigeration systems.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

The status of the claims is as follows:

1. A thermoelectric structure comprising:
a thin thermoelectric film extending in a plane between parallel first and second shorting bars; and
a plurality of curved ballistic scattering guides formed in a magnetic field region of the thin thermoelectric film subjected to a local, substantially uniform, nonzero magnetic field normal to the plane of the thin thermoelectric film.

2. The thermoelectric structure of claim 1, wherein the shape of the curved ballistic scattering guides substantially matches an arc of curvature of a charge carrier travelling in a charge transport direction between the first shorting bar and the second shorting bar through the magnetic field region.

3. The thermoelectric structure of claim 1, wherein the magnetic field is produced by a thin layer of magnetic material deposited at least atop or beneath the plane of the thin thermoelectric film, adjacent to the magnetic field region.

4. The thermoelectric structure of claim 1, wherein the adjacent curved ballistic scattering guides are separated by a distance of between 1 nm and 1 μm along an axis parallel to the first and second shorting bars.

5. The thermoelectric structure of claim 1, further comprising:
a first plurality of collimating scattering guides formed normal to the first and second shorting bars in a first collimating region subjected to negligible magnetic fields between the first shorting bar and the magnetic field region;
a second plurality of collimating scattering guides formed normal to the first and second shorting bars in a second collimating region subjected to negligible magnetic fields between the second shorting bar and the magnetic field region.

6. The thermoelectric structure of claim 5, wherein the curved ballistic scattering guides and the collimating scattering guides are formed by laser or mechanical scribing.

7. The thermoelectric structure of claim 5, wherein the curved ballistic scattering guides and the collimating scattering guides are formed by surface level or field doping.

8. The thermoelectric structure of claim 5, wherein the curved ballistic scattering guides and the collimating scattering guides are formed by lithographic patterning.

9. The thermoelectric structure of claim 5, wherein adjacent collimating ballistic scattering guides are separated by a distance between 1 nm and 1μ along an axis parallel to the first and second shorting bars.

10. The thermoelectric structure of claim 1, wherein the thin thermoelectric film has a thickness less than the electron mean free path in the thin thermoelectric film.

11. The thermoelectric structure of claim 1, wherein the curved ballistic scattering guides extend through the entire thickness of the thin thermoelectric film.

12. The thermoelectric structure of claim 1, wherein the thin thermoelectric film is formed of a semi-metal.

13. The thermoelectric structure of claim 1, wherein the thin thermoelectric film is formed of a high-mobility semiconductor.

14. The thermoelectric structure of claim 13, wherein the thin thermoelectric film is formed of a graphene.

15. The thermoelectric structure of claim 1, wherein the first and second shorting bars are formed of a conducting layer of doped material.
